(19) United States
(12) Patent Application Publication
(10) Pub. No.: US 2012/0061236 A1
(43) Pub. Date: Mar. 15, 2012

(54) METHOD FOR MACHINING A SUBSTRATE BY MEANS OF AN ION BEAM, AND ION BEAM DEVICE FOR MACHINING A SUBSTRATE

(75) Inventor: Sven Kiontke, Jena (DE)

(73) Assignee: asphericon GmbH

(21) Appl. No.: 13/226,423

(22) Filed: Sep. 6, 2011

(30) Foreign Application Priority Data
Sep. 7, 2010 (DE) 10 2010 040 324.5

(51) Int. Cl. C23C 14/46

(52) U.S. Cl. 204/192.34; 204/298.36

(57) ABSTRACT

In a method of machining a substrate by an ion beam, the ion beam is guided by an orifice plate formed at least partly of carbon-containing material. Between the orifice plate and the substrate, an educt that is reactive with carbon is guided such that carbon released from the orifice plate by the ion beam oxidizes. An ion beam device for machining a substrate includes an ion beam source and at least one orifice plate, disposed between the ion beam source and the substrate, for adjusting a cross section of and guiding the ion beam. The orifice plate is formed of carbon-containing material. A delivery unit, for delivering an educt that is reactive with carbon, is disposed such that the educt can be guided between the orifice plate and the substrate, so that carbon released from the orifice plate by the ion beam oxidizes.

The invention relates to a method for machining a substrate by means of an ion beam, which is generated by means of an ion beam source of an ion beam device and for machining the substrate is directed at a surface thereof, and the ion beam is guided by a orifice plate which is formed at least partly of carbon-containing material.

The invention further relates to an ion beam device for machining a substrate by means of an ion beam, including an ion beam source for generating the ion beam and at least one orifice plate, disposed between the ion beam source and the substrate, for adjusting a cross section of the ion beam, in which the ion beam can be guided by the orifice plate and in which the orifice plate is formed of carbon-containing material.

From the prior art it is generally known that especially for so-called micro- and nanotechnologies, precise machining of surfaces of a substrate is done. Not only a production of purposefully predeterminable layer thicknesses by means of so-called thinning down of layers by thin-film technology and a purposeful removal by abrasion of individual layers that are one atom thick, as well as nanoprofiling of so-called high-grade surfaces are done by means of ion beams.

Besides geometric changes in a surface topography of the substrate that are done by means of abrasion operations or coatings, in micro- and nanotechnologies local changes in properties of the surface are also of significance. It is known that in ion-beam-supported deposition methods, by means of a simultaneous arrival of ions during the coating on the substrate, the properties of the deposited layer are varied. Thus a density of the deposited layer can be variably predetermined, and growth of the layer from amorphous to crystalline states can be varied. The stoichiometry of the layer can be varied as well.

From the prior art, methods for machining a substrate by means of an ion beam and ion beam devices for machining a substrate are generally known. The ion beam device includes an ion beam source for generating the ion beam, and for machining the substrate, the ion beam is guided over at least one surface of the substrate. In the machining of the surface, either a defined surface structure is incorporated, or the surface is smoothed in some portions or completely, or surface shape deviations are reduced by local abrasion. The term “defined surface structure” is understood to mean all physical and chemical properties relating to defined two-dimensional regions of the surface, as well as surface topography. For precise positioning and dimensioning of the ion beam on the surface and for adjusting its cross section, an orifice plate is provided, which is disposed between the ion beam source and the substrate.

One such method and one such device for ion beam machining of a surface of a substrate are disclosed by European Patent EP 1 680 800 B1, in which the substrate is positioned opposite an ion beam that is generated by an ion beam source. A known pattern of properties of the surface of the substrate is partially machined by the ion beam in such a way that a new technologically defined pattern of properties is embodied. The actual geometric pattern of the effect of ion beam on the surface of the substrate is adjusted as a function of the known pattern of properties and of the new technologically defined pattern of properties, and also as a function of the progress of the method, by changing the beam characteristic and/or by pulsation of the ion beam. In the machining of the surface with the ion beam, a material abrasion volume is determined by means of a dwell time of the ion beam, a current flow, and an energy distribution of the ion beam.

German Patent Disclosure DE 41 08 404 A1 also discloses a method for controlling ion beam machining of solid-state surfaces, using a broad-beam ion source. A system located between the broad-beam ion source and a solid-state surface to be machined and comprising at least three orifice plates movable along a straight line independently of one another is varied, on the basis of both correction data and peripheral conditions, in time-optimized fashion according to the invention in terms of positioning time, shaping time, and opening time for zonal and local surface machining via a digital computer and actuator system using a simulation machining strategy, so that, depending on the requirements for precision, arbitrary surface machining can be performed.

European Patent EP 2 026 373 A 1 describes a positioning device for positioning an orifice plate in an ion beam of an ion implantation system. The positioning device includes two device parts, adjustable relative to one another by means of at least one positioning drive, of which parts, one can be or is connected to an abutment point disposed in stationary fashion relative to an ion beam source, and the other can be or is connected to the orifice plate. The second device part, together with a ground plate, electrode plate, and the orifice plate disposed on it, can be positioned relative to the ion beam in the three directions in space with the aid of electric positioning drives. The orifice plate comprises graphite that is impermeable to the ion beam.

From Japanese Patent Disclosure JP 62018030 A, a method for improving operation of an ion beam etching device is known, in which an etching region is periodically subjected to a cleaning plasma, for cleaning between continuous etching processes. As the cleaning plasma, an oxygen-containing gas is employed, which is guided in the etching region between an ion source that generates the ion beam and a substrate that is to be machined by means of the ion beam. Carbon deposited in the etching region oxidizes with the oxygen-containing gas, so that carbon dioxide or carbon monoxide is produced, which is carried away through a suction extraction opening.

From U.S. Pat. No. 6,394,109 B1, a device and a method for removing carbon contaminants are also known. The carbon contaminants occur during the production of semiconductor wafers by a lithography process involving charged particles on a mask, or in a machining chamber for performing the production. The carbon contaminants are removed from the mask or the machining chamber by means of an oxidant. A source for generating the charged particles is located in the machining chamber, and the oxidant is introduced nondirectionally into the machining chamber. The oxidant includes components of oxygen, ozone, dinitrogen monoxide, water vapor, doped oxygen compounds, and alcohols.

It is the object of the invention to disclose a method for operating an ion beam device that is improved over the prior art and an improved ion beam device for machining a substrate.

With regard to the method, the object is attained according to the invention by the characteristics recited in claim 1 and with regard to the ion beam device by characteristics recited in claim 11.

Advantageous embodiments of the invention are the subject of the dependent claims.

In a method for machining a substrate by means of an ion beam, the ion beam is generated by means of an ion beam source of an ion beam device and for machining the substrate is directed at a surface thereof; the ion beam is guided by an orifice plate, which is formed at least in part of carbon-containing material.

According to the invention, between the orifice plate and the substrate, an educt that is reactive with carbon is guided in a directional flow in such a way that carbon released from the orifice plate by means of the ion beam oxidizes. As a result, it is possible by means of the ion beam to oxidize carbon that has detached from the orifice plate and thus to avoid or at least reduce any penetration of the carbon into the surface of the substrate or a deposition of the carbon on the surface of the substrate. The result is advantageously that substrates of especially high surface quality can be produced. Particularly optical substrates, such as lenses, require especially high surface quality and purity of the material, which by the use of the method of the invention can be ensured in an especially simple, precise, and efficient way, in that the surface of the substrate is in particular smoothed and/or shape-corrected.

The educt is also preferably moved in contactless fashion past the orifice plate, so that a reaction of the carbon contained in the orifice plate with the educt and ensuing damage to the orifice plate are avoided. To that end, the educt is guided in a directional flow between the orifice plate and the substrate, so that carbon released from the orifice plate by means of the ion beam oxidizes.

In an especially advantageous embodiment, the oxidized carbon is carried away in the flow of educt, so that striking of the surface of the substrate by the oxidized carbon is prevented. The result is optimized surface machining and an optimized surface quality of the substrate.

As the educt, a plasma or gas is used in particular, which in each case can be guided simply and very precisely into the space between the orifice plate and the substrate.

To achieve the most complete possible oxidation of the carbon, in one embodiment oxygen, ozone, dinitrogen monoxide, water vapor, and/or oxygen-containing compounds and/or an oxygen-containing plasma is used as the gas.

To remove any carbon that has penetrated the surface of the substrate and/or has been deposited on the surface of the substrate after the machining of the substrate has been done, in a particular embodiment an oxygen-containing plasma, for instance an oxygen plasma, is guided onto the surface of the substrate. As a result, unoxidized or only partly oxidized carbon is released from the surface, and thus the surface quality of the substrate is improved further.

A particular advantage of the use of the oxygen-containing plasma for eroding the remaining carbon from the surface is that carbon also oxidizes especially effectively whenever it has already been deposited and thus itself is not very reactive, so that it is essentially the carbon that is abraded, and any additional abrasion of surface material of the substrate is minimized.

Alternatively or in addition, after the machining of the surface by means of the ion beam, the orifice plate is removed, and a carbon-free ion beam is guided onto the surface of the substrate, so that after the machining of the surface, any carbon that has penetrated the surface of the substrate and/or been deposited on the surface of the substrate can be removed.

The ion beam device for machining a substrate by means of an ion beam includes an ion beam source for generating the ion beam and at least one orifice plate, disposed between the ion beam source and the substrate, for adjusting the cross section of the ion beam; the ion beam can be guided by the orifice plate, and the orifice plate is formed of carbon-containing material.

According to the invention, a delivery unit for delivering an educt that is reactive with carbon is provided, and the delivery unit is disposed such that the educt can be guided in a directional flow between the orifice plate and the substrate, so that carbon released from the orifice plate by means of the ion beam oxidizes. Integrating the delivery unit can be done at low cost in terms of material, assembly and expenses, so that it is possible, at especially little effort and expense, to machine the surface of the substrate in a simple, precise and efficient way, and at the same time to avoid or at least reduce any penetration of the carbon into the surface of the substrate or any abrasion of the carbon on the surface of the substrate.

In a refinement of the ion beam device of the invention, the orifice plate can be taken off and/or pivoted all the way out of a propagation range of the ion beam. Thus on the one hand, in a simple way, various orifice plates can be disposed between the ion beam source and the substrate, so that different ion beams can be generated and different surface machining operations on the substrate are possible. On the other, because of the removability and/or pivotability of the orifice plate, there is the advantage that this orifice plate can be positioned entirely outside the region between the ion beam source and the substrate, for the sake of applying the ion beam over the surface.

In an especially advantageous embodiment of the ion beam device of the invention, a plurality of orifice plates are disposed pivotably in the vicinity between the ion beam source and the substrate, and the orifice plates are preferably disposed in rotary fashion. The result is a reduction in the effort and expense on changing the orifice plates for the different surface machining operations on the substrate.

For removing the oxidized carbon, in one embodiment of the ion beam device of the invention, a suction extraction unit is provided. The result is the possibility of effective, complete removal of the oxidized carbon and in particular the purposeful delivery of the reaction products into a filter and/or catalyst unit, for cleaning the reaction products that are produced in the reaction of the carbon with the educt.

A particular embodiment of the invention provides that the carbon orifice plate is cooled by means of a cooling device. As a result, the proportion of the carbon released by the ion beam from the inner surface of the orifice plate is reduced. In addition, material back-sputtered onto the orifice plate on the outside from the substrate adheres better to the orifice plate, so that the degree of contamination on the substrate is effectively reduced.

Especially preferably, the educt is delivered in the vicinity of a focus of a focusing ion beam and/or in the vicinity of a point on the substrate that is to be machined by means of the ion beam.

Preferably, an ion beam with ions having a speed between 300 eV and 1300 eV, in particular between 600 eV and 1000 eV, or between 700 eV and 900 eV, is employed. As a result, on the one hand an energy input is high enough to enable effective surface machining, and on the other, it is low enough to prevent deep destruction of the surface of the substrate. The speed of the ions determines the energy of the ion beam I and can be adjusted by means of the magnitude of an acceleration voltage that is applied to the gratings of the focusing unit 1.1.2.

Exemplary embodiments of the invention will be described in further detail below in conjunction with the drawings.

In the drawings:

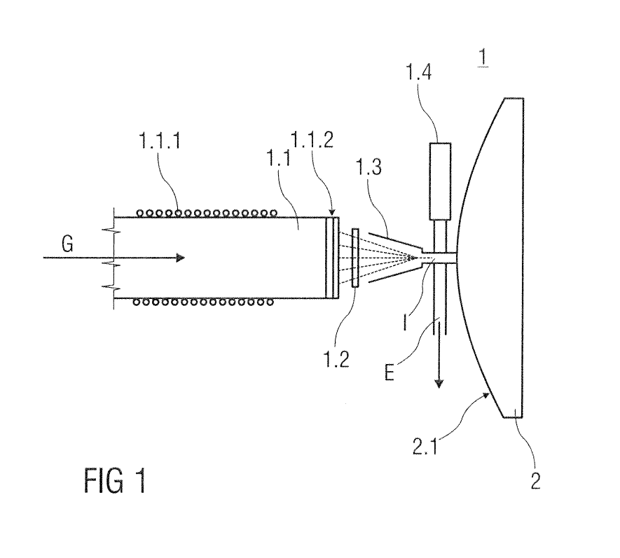

FIG. 1 schematically shows one exemplary embodiment of a first embodiment of an ion beam device according to the invention for machining a substrate by means of an ion beam;

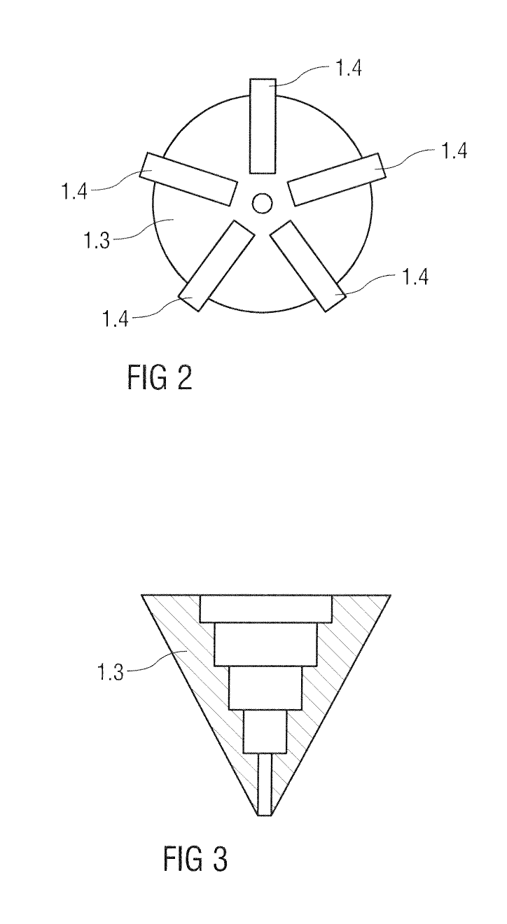

FIG. 2 is a fragmentary schematic frontal view of a second embodiment of an ion beam device according to the invention; and

FIG. 3 schematically shows one exemplary embodiment of a first embodiment of an orifice plate of the ion beam device of the invention.

In FIG. 1, one exemplary embodiment of the ion beam device I according to the invention for machining a substrate 2 by means of an ion beam I is shown.

The substrate 2 is a workpiece embodied as an optical lens, mirror, etc.; by means of the ion beam I, a defined structure is made in a surface 2.1 of the lens, or the surface 2.1 is smoothed and/or shape-corrected.

For generating the ion beam I, the ion beam device 1 includes an ion beam source 1.1, to which an argon gas G is delivered. The argon gas G is in particular delivered at a volumetric flow of 3 scm³/s (standard cubic centimeters per second) to 5 scm³/s. The use of other gases is alternatively possible. Alternatively, other volumetric flows are also possible, and the volumetric flow is preferably individually adjustable.

The ion beam I is generated by acceleration of the ions of the argon gas G; for generating a plasma in a pot 1.1.3, an electrical coil 1.1.1 is provided, which generates an electric alternating field. The ion beam I is formed in that ions of carbon, by means of a focusing unit 1.1.2 which is preferably formed by three curved and differently electrically charged gratings, are extracted from the plasma and accelerated in the direction of the substrate 2 to be machined.

Inside the ion beam device 1, a so-called high vacuum prevails. The ion beam source 1.1 and the substrate 2 are disposed inside a maximally empty space, not shown in further detail, in which the high vacuum is generated.

When the ion beam I strikes the surface 2.1 of the substrate 2, a pulse transfer takes place from the high-energy ions located in the ion beam I to the substrate 2, so that molecules and/or atoms are extracted from the surface 2.1 of the substrate 2 and thus removed by abrasion. This process is also known as sputtering.

In the exit direction of the ion beam I downstream of the focusing unit 1.1.2, there is also a spiral-wound filament 1.2, by means of which electrons with a low energy are generated. These electrons recombine on the surface 2.1 with the argon ions of the ion beam I after those have struck the surface 2.1. This prevents positive electrical charging of the surface 2.1 of the substrate 2 that would result from the bombardment of the surface 2.1 with the argon ions. This means that the substrate 2 remains electrically neutral.

For the directional guidance of the ion beam I and for adjusting a cross section of the ion beam I, and in particular for adjusting the cross section of the ion beam I on the surface 2.1 of the substrate 2, the ion beam device 1 has an orifice plate 1.3. As a result, it is possible to guide the ion beam I to defined positions on the surface 2.1.

The orifice plate 1.3 is disposed between the ion beam source 1.1 and the substrate 2 and at the outlet it has a defined diameter, by means of which a reduction in the power of the ion beam I, and in particular a machining diameter thereof, can be predetermined, and thus the abrasion from the surface 2.1 can be regulated. The diameter of the exit opening of the orifice plate 1.3 is selected for instance such that 50% or 90% or 99% of the argon ions are shielded or kept back from the ion beam I.

The orifice plate 1.3 is preferably disposed at a spacing of 6 mm in front of the surface 2.1 of the substrate 2. Alternatively, still other spacings are possible, and the substrate 2 can be disposed variably relative to the orifice plate 1.3, the orifice plate 1.3 can be disposed variably relative to the substrate 2, and/or the orifice plate 1.3 can be disposed variably relative to the ion beam source 1.1. The spacing between the orifice plate 1.3 and the surface 2.1 is in particular from 2 mm to 10 mm. A spacing between the ion beam source 1.1 and the substrate 2 is also preferably variably adjustable. A spacing between the ion beam source 1.1 and the orifice plate 1.3 is preferably variably adjustable as well.

In an exemplary embodiment not shown in further detail, the ion beam device 1 has a plurality of orifice plates 1.3, which are disposed in rotary fashion. The orifice plates 1.3 have various dimensions and in particular various diameters and/or shapes of the outlet openings, in order to generate various cross sections of the ion beam I.

The orifice plates 1.3 are disposed rotatably or pivotably in front of the ion beam source 1.1, so that the desired properties of the ion beam I can be predetermined by means of simple rotation of the turret and the ensuing positioning of the respective orifice plate 1.3 between the surface 2.1 of the substrate 2 and the ion beam source 1.1. One such turret has four orifice plates 1.3, which are characterized by different diameters of the outlet opening. The diameters amount to 3 mm, 1.5 mm, 1 mm, and 0.5 mm. Alternatively, turrets with a different number of orifice plates 1.3 and/or different orifice plate diameters are possible. Preferably, a position can be established in which the orifice plate does not affect the ion beam I, and in particular reduce it, at all.

To enable the shielding or keeping back of the argon ions, it is necessary that the orifice plate 1.3 comprise material that is impermeable to the ion beam I. Graphite, that is, carbon, is especially suitable for this purpose, since it has a low sputtering rate. However, carbon is released from the solid composition of the orifice plate 1.3 by the ion beam I and partly transported along with the ion beam I in the direction of the surface 2.1 of the substrate 2.

Since the carbon released from the orifice plate 1.3 has a relatively low energy of approximately 10 eV, it adheres especially well to the surface 2.1 of the substrate. The result of the adhesion of the carbon is worsening of the surface quality of the substrate 2, and in particular worsening of the optical properties of the lens, and especially worsening of their transmission. It is therefore necessary to avoid or at least reduce adhesions of carbon on the surface 2.1 of the substrate 2 and penetration of the carbon into the substrate 2.

To that end, the ion beam device 1 includes a delivery unit 1.4, by means of which an educt E that is reactive with carbon is guided in a directional flow between the orifice plate 1.3 and the surface 2.1, to be machined, of the substrate 2. The educt E is an oxygen-containing gas, which in the chemical reaction with carbon leads to an oxidation of the carbon in accordance with the following equation:

2C+O₂->2CO. [1]

Carbon monoxide occurs as the reaction product.

Alternatively or in addition, the carbon is oxidized to carbon dioxide in accordance with the following equation:

C+O₂->CO₂. [2]

To achieve the realization of the carbon, oxygen, ozone, dinitrogen monoxide, water vapor, and/or other oxygen-containing compounds are employed as the educt E, or in other words as the gas, and are guided by the delivery unit 1.4 in the directional flow between the orifice plate 1.3 and the surface 2.1 of the substrate 2. To avoid damage to or destruction of the orifice plate 1.3, the educt E is moved past the orifice plate 1.3 in contactless fashion.

In particular, the educt E is delivered at a volumetric flow of 0.3 cm³/s to 0.5 cm³/s. Alternatively, other volumetric flows are possible, and the volumetric flow is preferably individually adjustable. Advantageously, the volumetric flow of the educt E amounts to between 5% and 15%, and especially preferably 10%, of the volumetric flow of the argon gas introduced.

In order for any unoxidized carbon that has been deposited on the surface 2.1 of the substrate 2 to be removed from the substrate, after the machining of the surface 2.1 of the substrate 2 performed by means of the ion beam I an oxygen-containing plasma is guided onto the surface 2.1 of the substrate 2, and by means of it the carbon is oxidized and removed by abrasion from the surface 2.1. The surface 2.1 of the substrate 2 itself is unchanged, or changed only insubstantially, in the process.

Alternatively or in addition for this purpose, after the machining of the surface 2.1 with the ion beam I, the orifice plate 1.3 is taken off or pivoted all the way out of the propagation range of the ion beam. Alternatively, the substrate 2 is moved to a second source, which emits an oxygen-containing plasma.

Moreover, alternatively or in addition, after the machining of the surface 2.1 of the substrate 2 performed by means of the ion beam I, a carbon-free or at least low-carbon ion beam I is guided, and by means of it the carbon is removed by abrasion from the surface 2.1. An at least low-carbon ion beam I can be generated by not using any orifice plate comprising carbon; such an ion beam I has only a slight proportion of carbon, which has been extracted from the carbon gratings of the focusing unit 1.1.2.

It is especially effective, for removing unoxidized carbon that has been deposited on the surface 2.1 of the substrate 2, to employ an ion beam device with a focusing unit 1.1.2 but without an orifice plate 1.3, and to deliver the educt E by means of the delivery units 1.4.

In FIG. 2, an exemplary embodiment is shown in which a plurality of delivery units 1.4 is disposed in the vicinity of the orifice plate 1.3.

FIG. 3 shows an exemplary embodiment of a special orifice plate 1.3, whose outer region, oriented toward the substrate 2, is embodied in inclined fashion in the vicinity of its opening, so that the opening region of the orifice plate 1.3 is frustoconical from outside. As a result, surprisingly, a deposition of carbon on the substrate 2 to be machined is additional reduced, since ions that are reflected by the substrate 2 and that strike the orifice plate 1.3 from outside are extracted, if at all, from that same carbon only in a direction that does not extend in the direction of the substrate 2.

The inside of the orifice plate 1.3, in a further independent embodiment of the invention, has portions that extend essentially perpendicular to the ion beam I; that is, their normals have an inclination of less than 30°, and especially preferably less than 20°, to the direction of the ion beam I, so that ions that strike these portions of the orifice plate 1.3 extracted from the same carbon essentially in a direction which likewise does not extend in the direction of the substrate 2.

### LIST OF REFERENCE NUMERALS

1 Ion beam device
1.1 Ion beam source
1.1.1 Coil
1.1.2 focusing unit
1.1.3 Pot
1.2 Spiral-wound filament
1.3 Orifice plate
1.4 Delivery unit
2 Substrate
2.1 Surface
E Educt
G Argon gas
I Ion beam

1. A method for machining a substrate by means of an ion beam, which is generated by means of an ion beam source of an ion beam device and for machining the substrate is directed at a surface thereof, and the ion beam is guided by a orifice plate which is formed at least partly of carbon-containing material,
wherein, between the orifice plate and the substrate, an educt that is reactive with carbon is guided in a directional flow in such a way that carbon released from the orifice plate by means of the ion beam (I) oxidizes.

2. The method as defined by claim 1,
wherein the educt that is reactive with carbon is moved in contactless fashion past the orifice plate by means of a delivery unit, and the educt is guided in a directional flow between the orifice plate and the substrate, so that carbon released from the orifice plate by means of the ion beam oxidizes.

3. The method as defined by claim 1,
wherein the oxidized carbon is carried away in the flow of the educt.

4. The method as defined by claim 1,
wherein as the educt a gas or an oxygen-containing plasma is employed.

5. The method as defined by claim 4,
wherein as the gas, oxygen, ozone, dinitrogen monoxide, water vapor, and/or oxygen-containing compounds are employed.

6. The method as defined by claim 1,
wherein after the machining of the surface performed by means of the ion beam, an oxygen-containing plasma is guided onto the surface of the substrate.

7. The method as defined by claim 1,
wherein after the machining of the surface of the substrate performed by means of the ion beam, the orifice plate is removed, and a carbon-free or low-carbon ion beam, to which the educt is delivered, is guided onto the surface.

8. The method as defined by claim 1,
wherein the orifice plate is cooled by means of a cooling device.

9. The method as defined by claim 1,
wherein the educt is delivered in the vicinity of a focus of the ion beam and/or in the vicinity of a point on the substrate that is to be machined by means of the ion beam.

10. The method as defined by claim 1,
wherein an ion beam with ions having a speed between 300 eV and 1300 eV, in particular between 600 eV and 1000 eV, or between 700 eV and 9000 eV, is employed.

11. An ion beam device for machining a substrate by means of an ion beam, including an ion beam source for generating the ion beam and at least one orifice plate, disposed between the ion beam source and the substrate, for adjusting a cross section of the ion beam, in which the ion beam is guidable by the orifice plate and in which the orifice plate is formed of carbon-containing material,
wherein a delivery unit for delivering an educt that is reactive with carbon is provided, and the delivery unit is disposed such that the educt can be guided in a directional flow between the orifice plate and the substrate, so that carbon released from the orifice plate by means of the ion beam oxidizes.

12. The ion beam device as defined by claim 11,
wherein the orifice plate can be taken off and/or pivoted all the way out of a propagation range of the ion beam.

13. The ion beam device as defined by claim 11,
wherein the orifice plate is provided with a cooling device.

14. The ion beam device as defined by claim 11,
wherein the region of the orifice plate oriented toward the substrate is embodied in inclined fashion, in particular frustoconically.

15. The ion beam device as defined by claim 11,
wherein the inside of the orifice plate has at least some portions which extend essentially perpendicular to the ion beam.
